(19) United States
(12) Patent Application Publication
(10) Pub. No.: US 2014/0089761 A1
(43) Pub. Date: Mar. 27, 2014

(54) METHOD, APPARATUS AND SYSTEM FOR PROVIDING ERROR CORRECTION INFORMATION

(71) Applicant: Zion Kwok, Vancouver (CA)

(72) Inventor: Zion Kwok, Vancouver (CA)

(21) Appl. No.: 13/625,735

(22) Filed: Sep. 24, 2012

(51) Int. Cl. H03M 13/05

(52) U.S. Cl. 714/768; 714/E11.034

(57) ABSTRACT

A memory controller to detect for an unintentional access to an incorrect location of a memory device and to provide error detection for data retrieved from an intended location of the memory device. In an embodiment, the memory controller services a read request, including retrieving data and an error correction code from a memory location. In another embodiment, the retrieved error correction code is evaluated, based on a combination of the retrieved data and an address identifier of the read request, to determine whether the address identifier of the read request corresponds to the memory location from which the data and error correction code were retrieved.

### BACKGROUND

1. Technical Field

The present invention relates generally to the field of memory and computer memory systems and, more particularly but not exclusively, to error detection and correction for memory errors.

2. Background Art

Soft errors in data storage elements, such as cells of a memory device, occur when incident radiation charges or discharges the storage element, thereby changing its binary state. Soft errors are increasingly a concern with smaller scale fabrication processes as the size (hence, the capacitance) of the storage elements shrink, since incident radiation will have greater effect in causing the soft errors on such smaller scale storage elements. Previously, soft errors were statistically significant only for large and dense storage structures, such as cache memories. However, the smaller feature structures of next-generation memory devices are now more prone to having soft errors.

A problem with soft errors is that they have a tendency to silently corrupt data. This type of silent data corruption (SDC) is not desirable, particularly in a hard drive and/or a solid-state drive (SSD) of a computer system. Compounding the problem of SDC is the possibility that the servicing of a request to access a given addressable location of a memory—e.g. to write data to that location and/or to read data from that location—may instead result in the accessing of a different addressable location of that memory. Such erroneous memory accessing can be caused, for example, by corrupted address bits or bugs in hardware or firmware. Unintentional accessing of an incorrect memory location may not be detected by conventional error correction mechanisms where, for example, such accessing reads data and a corresponding error correction code which correctly identifies a parity value for that data, as it was originally written to the incorrect location.

### BRIEF DESCRIPTION OF THE DRAWINGS

The various embodiments of the present invention are illustrated by way of example, and not by way of limitation, in the figures of the accompanying drawings and in which:

FIG. 1 is a block diagram illustrating elements of a memory system for providing error correction information according to an embodiment.

FIG. 2A is a block diagram illustrating elements of a decoder device for reading access error correction information according to an embodiment.

FIG. 2B is a block diagram illustrating elements of an encoder device for writing access error correction information according to an embodiment.

FIG. 3 is a flow diagram illustrating elements of a method for decoding error correction information according to an embodiment.

FIG. 4 is a flow diagram illustrating elements of a method for encoding error correction information according to an embodiment.

FIG. 5 is a block diagram illustrating elements of a memory device for storing an error correction code according to an embodiment.

FIG. 6 is a block diagram illustrating elements of a computer platform for providing error correction according to an embodiment.

FIG. 7 is a block diagram illustrating elements of a mobile device for providing error correction according to an embodiment.

### DETAILED DESCRIPTION

Embodiments discussed herein variously provide mechanisms and/or techniques to detect for an unintentional access to an incorrect memory location, in conjunction with providing for error detection and, in an embodiment, error correction. Certain embodiments provide improvements in memory utilization for facilitating such address verification and error detection/correction.

By way of illustration and not limitation, a memory controller may receive a write request including data and an address identifier, the write request requesting that the data be stored at a memory location which corresponds to the address identifier. The memory controller may service the write request—e.g. wherein logic of the memory controller determines a value which is a combination of both the data and the address identifier of the write request. The memory controller may further calculate an error correction code for the determined combination, where servicing the write request further includes sending both the calculated error correction code and the data of the write request for storage in a location of the memory device.

Including such an error correction code for storage with the data of the write request allows for subsequent detection of whether the data was incorrectly written to another location which does not correspond to the address identifier of the write request, or incorrectly retrieved instead of data from another location which does not correspond to the address identifier of the write request. The address identifier may be subsequently recovered based on the error correction code only where such recovery is further based on the data stored with the error correction code. In an embodiment, servicing of the write request does not store to the location of the memory device any identifier of an address corresponding to the location, where such storing is in addition to storing the data and the error correction code. For example, the memory location may not store any address identifier for the location which is distinct from the stored data and error correction value. Accordingly, a larger portion of the memory location may be available for storage of payload data of the write request.

Additionally or alternatively, such a memory controller may receive a read request including an address identifier, the read request requesting that data be retrieved from a memory location which corresponds to the address identifier. The memory controller may service the read request, including retrieving data and an error correction code from a location of a memory device. Logic of the memory controller may determine a value which is a combination of the retrieved data and the address identifier of the read request. With the determined value and retrieved error correction code, the memory controller may determine whether the address identifier of the read request corresponds to the memory location from which memory controller retrieved the data and error correction code. For example, the memory controller may calculate an error correction code for the determined combination, and compare the calculated error correction code with the retrieved error correction code.

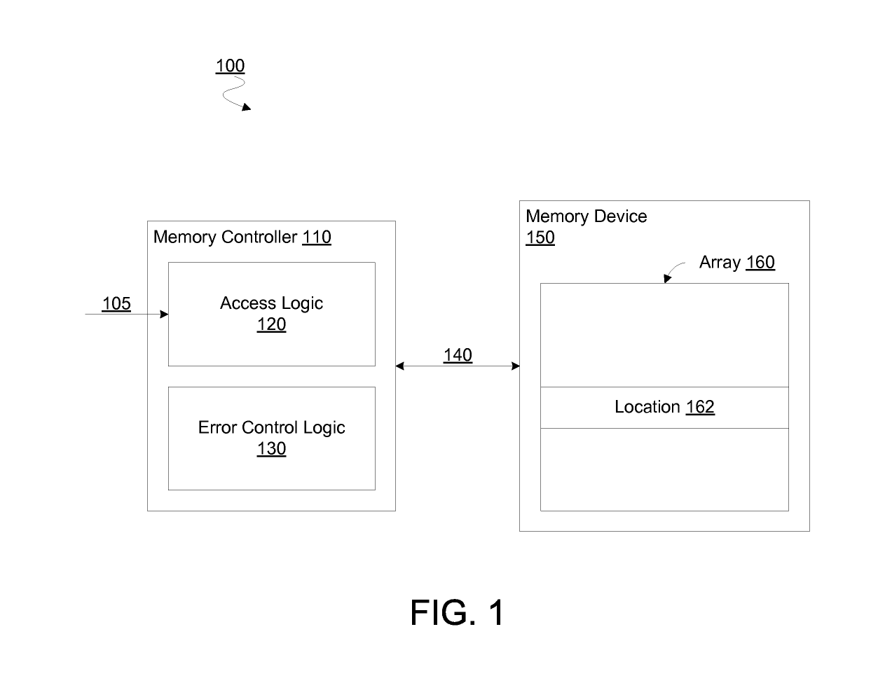

FIG. 1 shows elements of an illustrative computer system 100 for providing error correction information according to an embodiment. Computer system 100 may, for example, include a hardware platform of a personal computer such as a desktop computer, laptop computer, a handheld computer—e.g. a tablet, palmtop, cell phone, media player, and/or the like—and/or other such computer system. Alternatively or in addition, computer system 100 may provide for operation as a server, workstation, or other such computer system. In an embodiment, computer system 100 includes logic to access an error correction code for a combination of an address specifying a memory location and data stored in that memory location.

Computer system 100 may include memory device 150 to store data and memory controller 110 to coupled to memory device 150—e.g. via one or more signal lines 140—for controlling access to memory device 150. One or more signal lines 140 may include one or more of a data bus, control bus, address bus, clock signal line, power supply line and/or the like. In an embodiment, memory device 150 comprises random access memory (RAM) including, but not limited to, one or more of dynamic RAM (DRAM), static RAM (SRAM), synchronous DRAM (SDRAM), double data rate (DDR) SDRAM (DDR-SDRAM), Rambus DRAM (RDRAM), flash memory, non-volatile static RAM (nvSRAM), ferroelectric RAM (FRAM), magnetoresistive RAM (MRAM), phase-change memory (PCME) or any of a variety of other memory hardware. Memory device 150 may include a solid state drive (SSD) and/or a hard disk drive (HDD) of computer system 100, although certain embodiments are not limited in this regard. Operations of memory controller 110 to access memory device 150 may be in addition to those to access one or more other memory devices (not shown) of computer system 100.

In an embodiment, memory device 150 includes array 160 of locations including, for example an illustrative location 162. Each location of array 160 may be addressable by a different respective address. For example, memory device 150 (and, in embodiment, memory controller 110) may access data of location 162 by referencing a physical address specific to location 162. Additionally or alternatively, memory controller 110 may access location 162 by referencing a logical address corresponding to such a physical address. Any of a variety of conventional addressing schemes may be used for memory controller 110 and/or memory device 150 to reference locations of array 160 each with a respective location-specific address, according to different embodiments.

Memory controller 110 may include circuit logic for implementing any of a variety of conventional techniques for controlling access to memory device 150. By way of illustration and not limitation, memory controller 110 may comprise logic for processing one or more requests 105 received by memory controller 110. One or more requests 105 may include a read request to retrieve stored data from array 160 and/or a write request to store data to array 160—e.g. where memory controller 110 receives one or more requests 105 from a host (e.g. including one or more processor cores, not shown) of computer system 100. Such logic of memory controller 110 may convert one or more requests 105 each into a corresponding set of signals to send to memory device 150 via one or more signal lines 140. Such logic may, for example, perform any of a variety of operations to provide address translation, data refreshes etc. and/or to order, synchronize or otherwise regulate exchanges via one or more signal lines 140 for accessing array 160.

Memory controller 110 may supplement conventional controller functionality with circuit logic to evaluate—e.g. calculate or otherwise process—an error correction code based on a combination of an address specifying a memory location and data stored in that memory location. By way of illustration and not limitation, memory controller 110 may include access logic 120 to receive one or more requests 105—e.g. from a central processing unit (CPU), graphics processor, co-processor or other agent (not shown) of computer system 100.

Access logic 120 may, for example, service a read request of one or more requests 105, the read request requesting retrieval of data stored in array 160. In an embodiment, the read request includes an address identifier specifying an address—e.g. including a physical address and/or a logical address—for a location in array 160. In an embodiment, access logic 120 operates with error control logic 130 of memory controller 110 to detect whether an incorrect location of array 160 is accessed in the servicing of the read request. For example, servicing such a read request may include access logic 120 retrieving from location 162 both data and an error correction code. Error control logic 130 may receive the address identifier of the read request, as well as both the data and the error correction code retrieved from location 162. With the retrieved error correction code, error control logic 130 may evaluate a combination of the address identifier of the read request and data retrieved from location 162. Based on the evaluation, error control logic 130 may signal whether location 162 corresponds to the address identifier of the read request.

Additionally or alternatively, access logic 120 may service a write request of one or more request s 105, the write request requesting that data be stored in array 160. In an embodiment, the write request includes an address identifier specifying an address for a location in array 160 and data to be written to that location. The address identifier may, for example, specify an address—e.g. logical or physical—for location 162, although certain embodiments are not limited in this regard. Access logic 120 may operate with error control logic 130 to include in the servicing of the write request a writing of error correction information to be available for later access and evaluation. For example, error control logic 130 may receive the data and the first address identifier of the write request and, in an embodiment, calculate an error correction code for a combination of the received address identifier and data.

In an embodiment, error control logic 130 may provide the calculated error correction code to access logic 120. Servicing the write request may include access logic 120 sending both the data of the write request and the error correction code received from error control logic 130 for storage in a location of a memory. In an embodiment, the write request is serviced independent of access logic 120 storing to array 160 any address identifier which corresponds to the location of array 160, where storing of any such address identifier is in addition to storing in array 160 the error correction code received from error control logic 130.

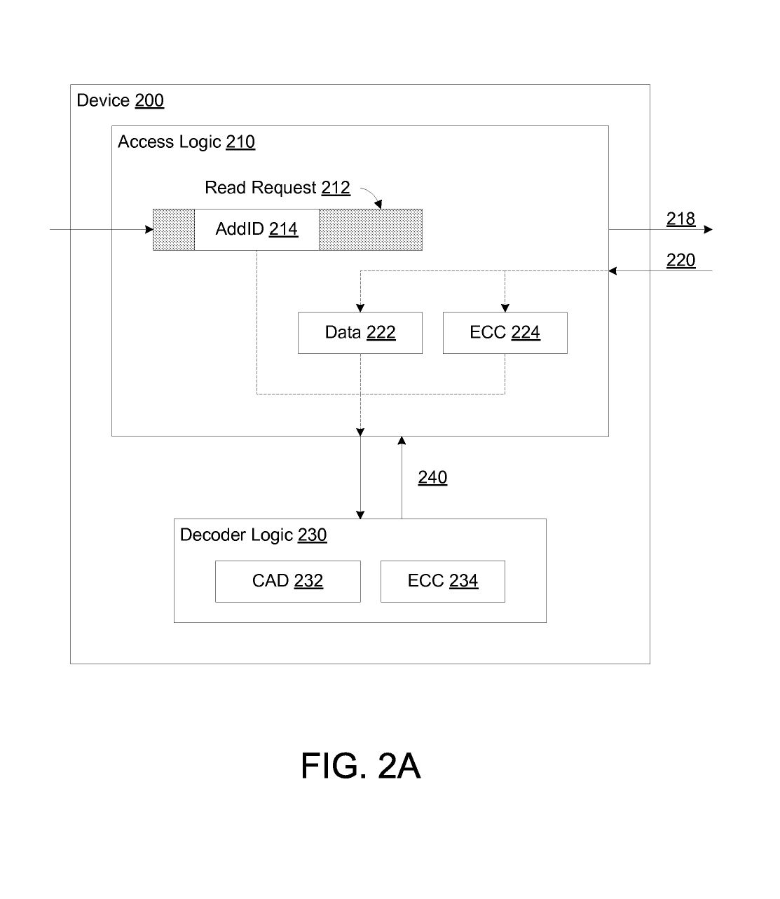

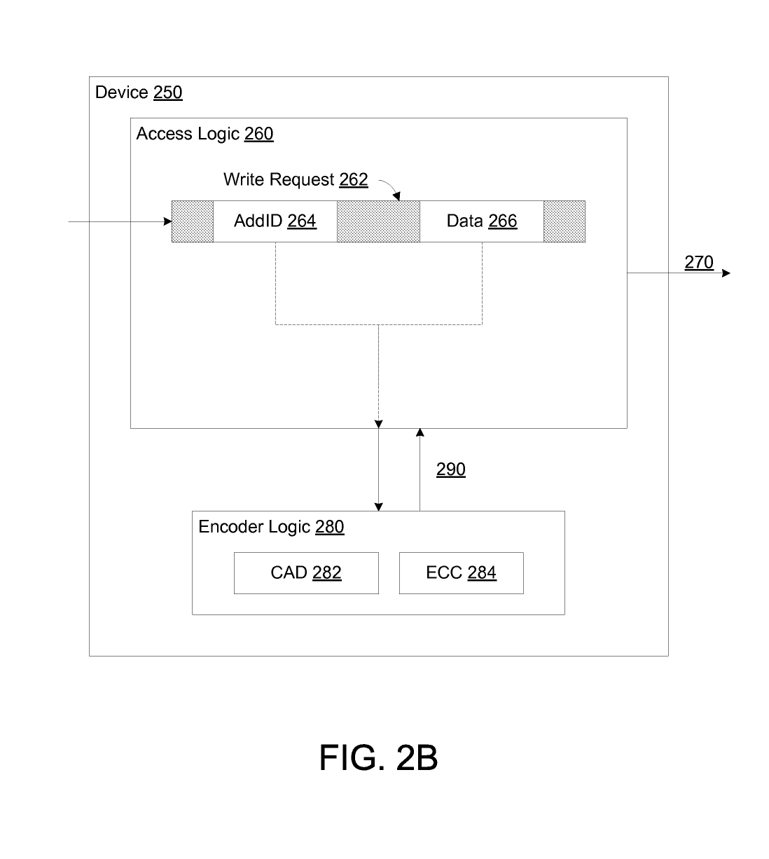

FIG. 2A illustrates elements of a device 200 for providing access to error correction information according to an embodiment. Device 200 may include some or all of the features of memory controller 110, for example. In an embodiment, device 200 operates to access one or more locations of a memory including memory device 150.

Device 200 may comprise access logic 210—e.g. including hardware, firmware and/or executing software—to service read request 212 including address identifier AddID 214. Read request 212 may be received by device 200 from a host of a computer system which includes device 200—e.g. where device 200 controls access by the host to an array of memory locations (not shown) of the computer system. Access logic 210 may include some or all of the features of access logic 120, for example.

Servicing read request 212 may include access logic 210 retrieving data 222 and error correction code 224 from a location of a memory. For example, access logic 210 may send to the memory device a read command 218 based on AddID 214, where the memory provides a response 220 to read command 218 which includes data 222 and error correction code 224. Error correction code 224 may, for example, include a value specifying a parity value for a combination of data 222 and address information. Alternatively or in addition, error correction code 224 may include a Hamming code, a Reed-Solomon code and/or any of a variety of additional or alternative error correction codes for such a combination.

In an embodiment, during servicing of read request 212, the memory location accessed by read command 218 does not store any address identifier for that memory location, where such an address identifier is in addition to data 222 and error correction code 224. For example, data 222 and error correction code 224 may be all information stored in the addressable location accessed by read command 218, although certain embodiments are not limited in this regard.

In an embodiment, device 200 further comprises decoder logic 230 to receive AddID 214 of read request 212 and both data 222 and error correction code 224 from response 220. Decoder logic 230 may include some or all of the features of error control logic 130, for example. Based on AddID 214 and data 222, decoder logic 230 may calculate or otherwise determine combination CAD 232 of AddID 214 and data 222—i.e. where CAD 232 is a value based on both AddID 214 and data 222. By way of illustration and not limitation CAD 232 may be an encoding of AddID 214 and data 222. Such encoding may include one or more arithmetic operations—e.g. including a concatenation operation, an addition operation, a shift operation and/or the like—for which AddID 214 and data 222 are operands. Error correction code 234 may, for example, include a value specifying a parity of CAD 232. Alternatively or in addition, error correction code 234 may include a Hamming code, a Reed-Solomon code and/or any of a variety of additional or alternative codes calculated based on CAD 232.

With the calculated CAD 232 and/or error correction code 234, decoder logic 230 may perform an evaluation of data 222 and/or error correction code 224 to determine whether data 222 includes an error and/or whether response 220 includes data retrieved from a location corresponding to AddID 214. In an illustrative scenario for one embodiment, such evaluation may include decoder logic 230 comparing error correction code 224 and error correction code 234 to determine whether (or not) they are equal to one another. In an embodiment, decoder logic 230 may determine, based on equality of error correction code 224 and error correction code 234, that there are no errors in data 222 and that response 220 is the result of a memory location corresponding to AddID 214 being accessed—e.g. rather than some other memory location being accessed in error.

In an illustrative scenario according to one embodiment, AddID 214 and data 222 may be concatenated to form the CAD 232, where AddID 214 is located in the first 8 bits of CAD 232. In such an instance, a bit error detected in the first 8 bits of the CAD 232, may indicate an error in AddID 214, which in turn indicates an unintended access to an erroneous memory location. Where these 8 bits of AddID 214 are not stored in the memory device, the error in CAD 232 must, in an embodiment, be the result of an address mismatch.

Where decoder logic 230 detects no errors in data 222 and that read command 218 accessed the location corresponding to AddID 214, decoder logic 230 may generate a signal 240 to communicate—e.g. to access logic 210—that device 200 may provide data 222 in a response to read request 212. Where decoder logic 230 detects that read command 218 accessed the location which does not correspond to AddID 214, signal 240 may communicate that servicing of read request 212 is unsuccessful. Where decoder logic 230 detects one or more errors in data 222 and that read command 218 accessed the location corresponding to AddID 214, signal 240 may communicate that error correction is to be performed for data 222 using error correction code 234. In an alternate embodiment, decoder logic 230 may perform such error correction—e.g. where signal 240 includes a resulting corrected version of data 222. Where decoder logic 230 detects that errors in data 222 are uncorrectable and that read command 218 accessed the location corresponding to AddID 214, signal 240 may indicate that the location corresponding to AddID 214 stores unusable information.

FIG. 2B illustrates elements of a device 250 for providing access to error correction information according to an embodiment. Device 250 may include some or all of the features of memory controller 110, for example. In an embodiment, device 250 provides some or all of the functionality of device 200.

Device 250 may comprise access logic 260 to service write request 262 received by device 250. Write request 262 may be received by device 250 from a host of a computer system which includes device 250—e.g. where device 250 controls access by the host to an array of memory locations (not shown) of the computer system. In an embodiment, write request 262 includes address identifier AddID 264 and data 266, where write request 262 requests that data 266 be stored in a memory location corresponding to AddID 264. Access logic 260 may include some or all of the features of access logic 120 and/or access logic 210, for example.

Servicing write request 262 may include access logic 260 sending data 266 and AddID 264 to encoder logic 280 of device 250. Encoder logic 280 may include some or all of the features of error control logic 130—e.g. where encoder logic 280 further provides some or all of the functionality of decoder logic 230. Based on AddID 264 and data 266, encoder logic 280 may calculate or otherwise determine combination CAD 282 of AddID 264 and data 266—i.e. where CAD 282 is a value based on both AddID 264 and data 266. By way of illustration and not limitation CAD 282 may be an encoding of AddID 264 and data 266. Such encoding may include performing one or more arithmetic operations—e.g. including a concatenation operation, an addition operation, a shift operation and/or the like—for which AddID 264 and data 266 are operands.

In an embodiment, encoder logic 280 may further calculate error correction code 284 for CAD 282. Error correction code 284 may, for example, include a value specifying a parity of CAD 282. Alternatively or in addition, error correction code 284 may include a Hamming code, a Reed-Solomon code and/or any of a variety of additional or alternative codes calculated based on CAD 282. Encoder logic 280 may subsequently communicate the calculated error correction code 284—e.g. in a signal 290 to access logic 260—for further servicing of write request 262.

Based on AddID 264 and data 266 of write request 262, and further based on receipt of the calculated error correction code 284, access logic 260 may send to the memory device a write command 270 for storing data 266 and error correction code 284 in a memory location which corresponds to AddID 264. In an embodiment, write request 262 is serviced independent of device 250 storing in the memory location any address identifier of the memory location, where storing of such address identifier is in addition to storing data 266 and error correction code 284 to that storage location.

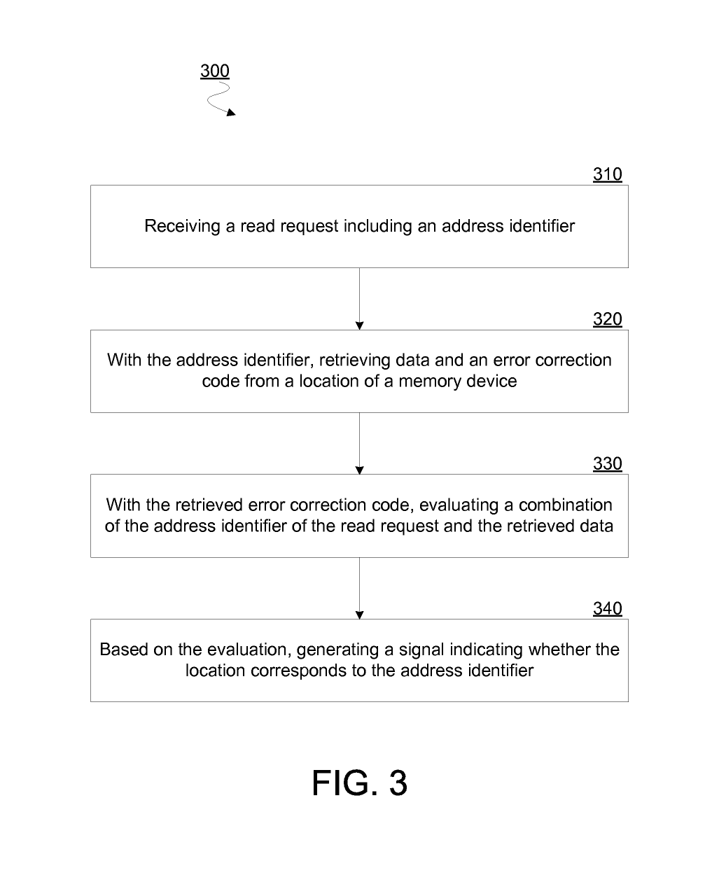

FIG. 3 illustrates elements of a method 300 for evaluating error correction information according to an embodiment. Method 300 may be performed by a controller device having some or all of the features of memory controller 110, for example. In an embodiment, method 300 is performed by circuitry having some or all of the functionality of device 200.

Method 300 may include, at 310, receiving a read request including an address identifier. The address identifier may include, for example, a logical address for a memory location and/or a physical address for the location. Method 300 may include servicing the read request received at 310. In an embodiment, servicing the read request includes, at 320, retrieving, with the address identifier of the read request, data and an error correction code from a location of the memory device. The error correction code retrieved at 320 may include one or more of a parity value, a Hamming code, a Reed-Solomon code and/or any of a variety of other types of error correction codes. Servicing the read request may include accessing a memory location while the memory location does not store any address identifier which is distinct from an error correction code stored in the location.

Servicing the read request may further include, at 330, evaluating a combination of the address identifier of the read request and the retrieved data. The evaluating at 330 may be performed with the error correction code retrieved at 320. By way of illustration and not limitation, the combination evaluated at 330 may include, for example, a concatenation of the data with the address identifier. In an embodiment, the evaluating at 330 includes calculating another error correction code for the combination and comparing the other error correction code with the error correction code retrieved at 320. Based on such a comparison, the evaluating at 330 may detect for an indication of an error in the retrieved data and/or detect for an indication that the data was retrieved from a location which does not correspond to the address identifier of the read request. Based on the evaluation at 330, method 300 may, at 340, generate a signal indicating whether the location corresponds to the address identifier. In another embodiment, the signal generated at 340 may additionally or alternatively indicate whether there is an error in the data retrieved at 320.

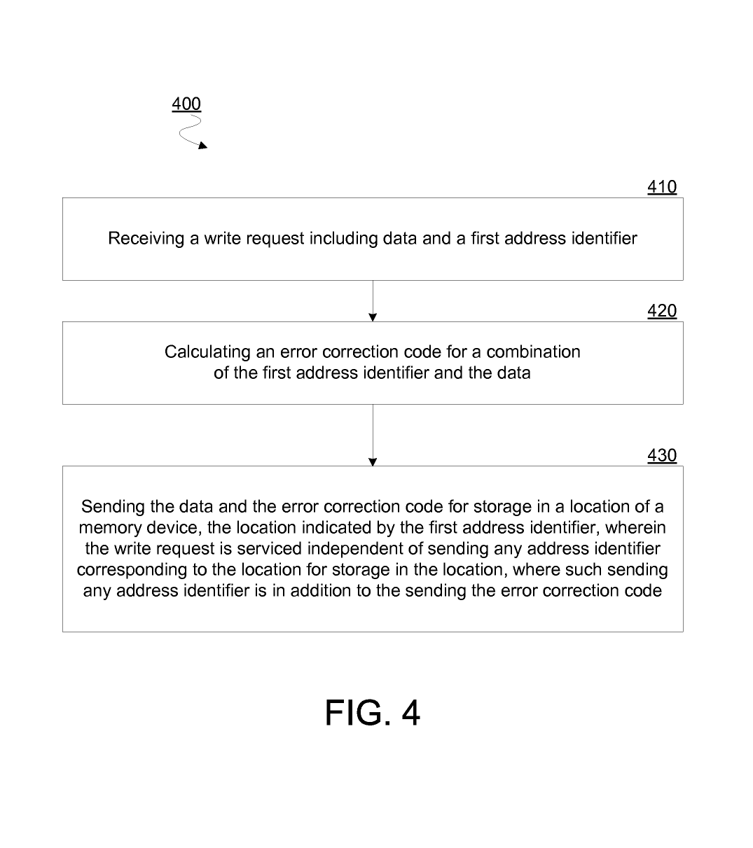

FIG. 4 illustrates elements of a method for generating error correction information according to an embodiment. Method 400 may be performed, for example, by circuit logic which provides some or all of the features of error control logic 130. Such logic may, for example, have some of all of the functionality of access logic 260 and/or encoder logic 280. Method 400 may be performed by a device which also performs method 300, although certain embodiments are not limited in this regard.

Method 400 may include, at 410, receiving a write request including data and a first address identifier. The address identifier may include, for example, a logical address for a memory location and/or a physical address for the location. The write request may request that the data be written to a location of a memory device which corresponds to the first address identifier.

Method 400 may include performing one or more operations to service the write request received at 410. Such servicing of the write request may include, at 420, calculating an error correction code for a combination of the first address identifier and the data of the write request. In an embodiment, calculating the error correction code includes generating a value which is a combination of the data and the first address identifier. Generating such a combination may, for example, include performing a concatenation, addition, multiplication and/or other encoding operation to combine the data and the first address identifier. The error correction code calculated at 420 may include one or more of a parity value, a Hamming code, a Reed-Solomon code and/or any of a variety of other types of error correction codes for such a combination.

Servicing the write request may further include, at 430, sending the data and the error correction code calculated at 420 for storage in a location of a memory device, the location indicated by the first address identifier. In an embodiment, the write request received at 410 is serviced by method 400 independent of sending any address identifier corresponding to the location for storage in the location, where such sending of any address identifier is in addition to the sending of the error correction code.

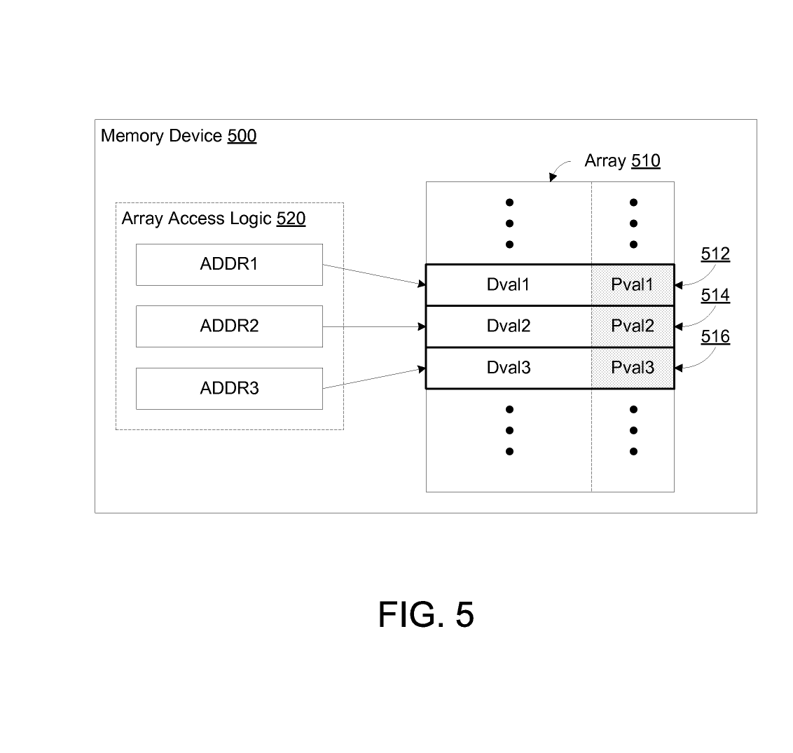

FIG. 5 illustrates elements of a memory device 500 for providing access to error correction information according to an embodiment. Memory device 500 may operate in a system including some or all of the features of computer system 100, for example. In an embodiment, access to memory device 500 is controlled with a memory controller having some or all of the features of memory controller 110. For example, memory device 500 may be accessed according to method 300 and/or according to method 400.

In an embodiment, memory device 500 includes array 510 of memory cells comprising a plurality of addressable locations—e.g. including illustrative locations 512, 514, 516. Memory device logic 500 may further include array access logic 520 including circuitry to selectively access various locations of array 510—e.g. in response to respective memory access commands which memory device 500 receives from a memory controller (not shown) coupled thereto. Array access logic 520 may, for example, include one or more of a row decoder, column decoder, sense amplifiers and/or any of a variety of other conventional mechanisms for writing data to array 510 and/or reading data from array 510—e.g. in support of a memory controller servicing a read request or write request. In an embodiment, functionality of array access logic 520 implements physical addresses which are each specific to a different respective location of array 510. By way of illustration and not limitation, array access logic 520 may implement physical addresses ADDR1, ADDR2, ADDR3 corresponding, respectively, to locations 512, 514, 516. ADDR1, ADDR2, ADDR3, which are represented as functional blocks of array access logic 520, may be implemented by any of a variety of conventional addressing mechanisms, which are not limiting on certain embodiments.

At a given time during operation of memory device 500, some or all of locations 512, 514, 516 may each store respective data and, in an embodiment, an error correction code. By way of illustration and not limitation, at some point in time, a portion of location 512 may store data value Dval1 while another portion of location 512 stores a corresponding error correction code Pval1 for the detection and correction of any error in Dval1. Alternatively or in addition, respective portions of location 514 may store data value Dval2 and corresponding error correction code Pval2 for Dval2, and/or respective portions of location 516 may store data value Dval3 and corresponding error correction code Pval3 for Dval3. Any of a variety of additional or alternative data and error correction code pairs may be stored in respective locations of array 510, according to different embodiments.

In an embodiment, the storing of data and a corresponding error correction value in a location of array 510 is based on functionality such as that of device 200. By way of illustration and not limitation, Pval1 of location 512 may be an error correction code for a combination of ADDR1 and Dval1. For example, Pval1 may be a parity value or other error correction code for an address/data combination such as a concatenation (ADDR1|Dval1) of the respective bits in ADDR1 and Dval1. Alternatively, Pval1 may be an error correction code for a combination of Dval1 and a logical address which the memory controller uses to indirectly reference physical address ADDR1.

In an embodiment, access to a location of array 510 according to techniques discussed herein avoids any storing in that location of an address identifier for that location, where storing such an address identifier is in addition to the storing of data and an error correction code. By way of illustration and not limitation, device 250 may service a write command by storing to location 514 both Dval2 and Pval2, where Pval2 is an error correction code for a value which is a combination of Dval2 and ADDR2 (or alternatively, a combination of Dval2 and a logical address for indirectly referencing ADDR2). Such servicing may be independent of device 250 storing ADDR2 (or, in an embodiment, any logical address for indirectly referencing ADDR2) to location 514. Foregoing storage of an address identifier to an addressable memory location may increase the amount of available space for data storage, resulting in improved efficiency in utilization of array 510.

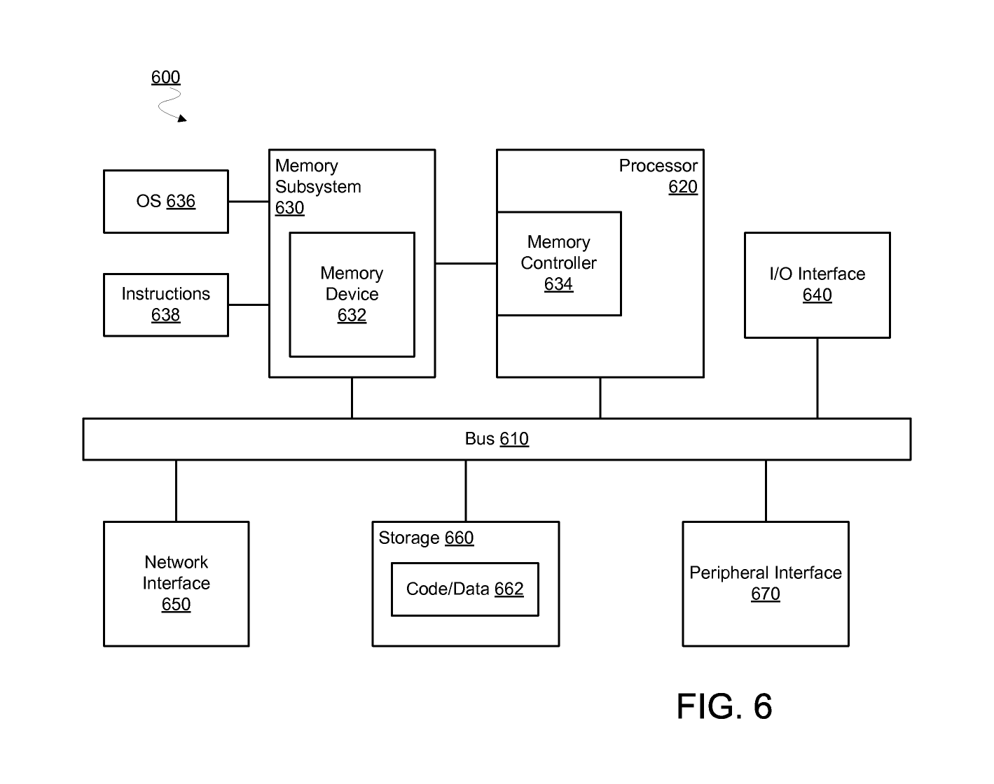

FIG. 6 is a block diagram of an embodiment of a computing system in which address validation and data error correction/detection can be implemented. System 600 represents a computing device in accordance with any embodiment described herein, and can be a laptop computer, a desktop computer, a server, a gaming or entertainment control system, a scanner, copier, printer, or other electronic device. System 600 includes processor 620, which provides processing, operation management, and execution of instructions for system 600. Processor 620 can include any type of microprocessor, central processing unit (CPU), processing core, or other processing hardware to provide processing for system 600. Processor 620 controls the overall operation of system 600, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 630 represents the main memory of system 600, and provides temporary storage for code to be executed by processor 620, or data values to be used in executing a routine. Memory subsystem 630 can include one or more memory devices such as read-only memory (ROM), flash memory, one or more varieties of random access memory (RAM), or other memory devices, or a combination of such devices. Memory subsystem 630 stores and hosts, among other things, operating system (OS) 636 to provide a software platform for execution of instructions in system 600. Additionally, other instructions 638 are stored and executed from memory subsystem 630 to provide the logic and the processing of system 600. OS 636 and instructions 638 are executed by processor 620.

Memory subsystem 630 includes memory device 632 where it stores data, instructions, programs, or other items. In one embodiment, processor 620 includes memory controller 634, which includes memory controller logic in accordance with any embodiment described herein—e.g. which detects for an unintentional access to an incorrect memory location, in conjunction with providing for error detection and, in an embodiment, error correction. Memory controller 634 may service a write request from a core of processor 620, including sending for storage in a location of memory device 632 data and an error correction code for a combination of the data and an address identifier included in the write request. In an embodiment, the write request is serviced independent of memory controller 634 storing to the location of memory device 632 any address identifier which corresponds to that location, where storing of any such address identifier is in addition to the storing of the error correction code. Memory controller 634 may additionally or alternatively service a read request from a processor core—e.g. including retrieving and evaluating data and an error correction code previously stored by such servicing of a write command. Memory controller 634 may alternatively be a component of memory subsystem 630, although certain embodiments are not limited in this regard.

Processor 620 and memory subsystem 630 are coupled to bus/bus system 610. Bus 610 is an abstraction that represents any one or more separate physical buses, communication lines/interfaces, and/or point-to-point connections, connected by appropriate bridges, adapters, and/or controllers. Therefore, bus 610 can include, for example, one or more of a system bus, a Peripheral Component Interconnect (PCI) bus, a HyperTransport or industry standard architecture (ISA) bus, a small computer system interface (SCSI) bus, a Universal Serial Bus (USB), or an Institute of Electrical and Electronics Engineers (IEEE) standard 1394 bus (commonly referred to as “Firewire”). The buses of bus 610 can also correspond to interfaces in network interface 650.

System 600 also includes one or more input/output (I/O) interface(s) 640, network interface 650, one or more internal mass storage device(s) 660, and peripheral interface 670 coupled to bus 610. I/O interface 640 can include one or more interface components through which a user interacts with system 600 (e.g., video, audio, and/or alphanumeric interfacing). Network interface 650 provides system 600 the ability to communicate with remote devices (e.g., servers, other computing devices) over one or more networks. Network interface 650 can include an Ethernet adapter, wireless interconnection components, USB (universal serial bus), or other wired or wireless standards-based or proprietary interfaces.

Storage 660 can be or include any conventional medium for storing large amounts of data in a nonvolatile manner, such as one or more magnetic, solid state, or optical based disks, or a combination. Storage 660 holds code or instructions and data 662 in a persistent state (i.e., the value is retained despite interruption of power to system 600). Storage 660 can be generically considered to be a “memory,” although memory 630 is the executing or operating memory to provide instructions to processor 620. Whereas storage 660 is nonvolatile, memory 630 can include volatile memory (i.e., the value or state of the data is indeterminate if power is interrupted to system 600). Address verification and error correction/detection mechanisms and techniques may, according to different embodiments, be applied for protecting accesses to memory subsystem 630 and/or storage 660, for example.

Peripheral interface 670 can include any hardware interface not specifically mentioned above. Peripherals refer generally to devices that connect dependently to system 600. A dependent connection is one where system 600 provides the software and/or hardware platform on which operation executes, and with which a user interacts.

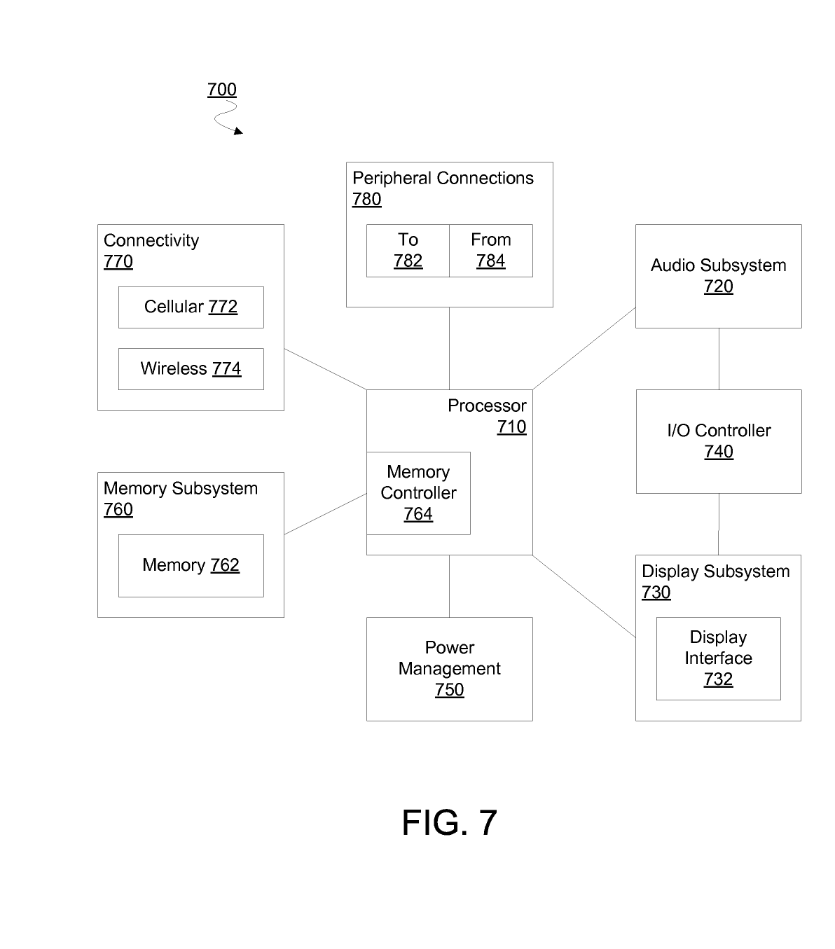

FIG. 7 is a block diagram of an embodiment of a mobile device in which address verification and error detection/correction can be implemented. Device 700 represents a mobile computing device, such as a computing tablet, a mobile phone or smartphone, a wireless-enabled e-reader, or other mobile device. It will be understood that certain of the components are shown generally, and not all components of such a device are shown in device 700.

Device 700 includes processor 710, which performs the primary processing operations of device 700. Processor 710 can include one or more physical devices, such as microprocessors, application processors, microcontrollers, programmable logic devices, or other processing means. In one embodiment, processor 710 includes optical interface components in addition to a processor die. Thus, the processor die and photonic components are in the same package. Such a processor package can interface optically with an optical connector in accordance with any embodiment described herein.

The processing operations performed by processor 710 include the execution of an operating platform or operating system on which applications and/or device functions are executed. The processing operations include operations related to I/O (input/output) with a human user or with other devices, operations related to power management, and/or operations related to connecting device 700 to another device. The processing operations can also include operations related to audio I/O and/or display I/O.

In one embodiment, device 700 includes audio subsystem 720, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into device 700, or connected to device 700. In one embodiment, a user interacts with device 700 by providing audio commands that are received and processed by processor 710.

Display subsystem 730 represents hardware (e.g., display devices) and software (e.g., drivers) components that provide a visual and/or tactile display for a user to interact with the computing device. Display subsystem 730 includes display interface 732, which includes the particular screen or hardware device used to provide a display to a user. In one embodiment, display interface 732 includes logic separate from processor 710 to perform at least some processing related to the display. In one embodiment, display subsystem 730 includes a touchscreen device that provides both output and input to a user.

I/O controller 740 represents hardware devices and software components related to interaction with a user. I/O controller 740 can operate to manage hardware that is part of audio subsystem 720 and/or display subsystem 730. Additionally, I/O controller 740 illustrates a connection point for additional devices that connect to device 700 through which a user might interact with the system. For example, devices that can be attached to device 700 might include microphone devices, speaker or stereo systems, video systems or other display device, keyboard or keypad devices, or other I/O devices for use with specific applications such as card readers or other devices.

As mentioned above, I/O controller 740 can interact with audio subsystem 720 and/or display subsystem 730. For example, input through a microphone or other audio device can provide input or commands for one or more applications or functions of device 700. Additionally, audio output can be provided instead of or in addition to display output. In another example, if display subsystem includes a touchscreen, the display device also acts as an input device, which can be at least partially managed by I/O controller 740. There can also be additional buttons or switches on device 700 to provide I/O functions managed by I/O controller 740.

In one embodiment, I/O controller 740 manages devices such as accelerometers, cameras, light sensors or other environmental sensors, gyroscopes, global positioning system (GPS), or other hardware that can be included in device 700. The input can be part of direct user interaction, as well as providing environmental input to the system to influence its operations (such as filtering for noise, adjusting displays for brightness detection, applying a flash for a camera, or other features).

In one embodiment, device 700 includes power management 750 that manages battery power usage, charging of the battery, and features related to power saving operation. Memory subsystem 760 includes memory device(s) 762 for storing information in device 700. Memory subsystem 760 can include nonvolatile (state does not change if power to the memory device is interrupted) and/or volatile (state is indeterminate if power to the memory device is interrupted) memory devices. Memory 760 can store application data, user data, music, photos, documents, or other data, as well as system data (whether long-term or temporary) related to the execution of the applications and functions of system 700.

In one embodiment, processor 710 includes memory controller 764 (which could also be considered part of the control of system 700, and could alternatively be part of memory subsystem 760). Memory controller 764 monitors for unintentional accesses to incorrect memory locations, in conjunction with providing for error detection and, in an embodiment, error correction. Such monitoring may be based, for example, on evaluation of an error correction code for a combination of data and address information. Memory controller 764 may service a write request from a core of processor 710, including sending for storage in a location of memory 762 data and an error correction code for a combination of the data and an address identifier included in the write request. The write request may be serviced, for example, independent of memory controller 764 storing to the location of memory 762 any address identifier which corresponds to that location, where storing of any such address identifier is in addition to the storing of the error correction code. Memory controller 764 may additionally or alternatively service a read request from a processor core—e.g. including retrieving and evaluating data and an error correction code previously stored by such servicing of a write command.

Connectivity 770 includes hardware devices (e.g., wireless and/or wired connectors and communication hardware) and software components (e.g., drivers, protocol stacks) to enable device 700 to communicate with external devices. The device could be separate devices, such as other computing devices, wireless access points or base stations, as well as peripherals such as headsets, printers, or other devices.

Connectivity 770 can include multiple different types of connectivity. To generalize, device 700 is illustrated with cellular connectivity 772 and wireless connectivity 774. Cellular connectivity 772 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 774 refers to wireless connectivity that is not cellular, and can include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 780 include hardware interfaces and connectors, as well as software components (e.g., drivers, protocol stacks) to make peripheral connections. It will be understood that device 700 could both be a peripheral device (“to” 782) to other computing devices, as well as have peripheral devices (“from” 784) connected to it. Device 700 commonly has a “docking” connector to connect to other computing devices for purposes such as managing (e.g., downloading and/or uploading, changing, synchronizing) content on device 700. Additionally, a docking connector can allow device 700 to connect to certain peripherals that allow device 700 to control content output, for example, to audiovisual or other systems.

In addition to a proprietary docking connector or other proprietary connection hardware, device 700 can make peripheral connections 780 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

In one aspect, a device comprises memory access logic to service a read request including an address identifier, including the memory access logic to retrieve, with the address identifier, data and an error correction code from a location of a memory. The device further comprises decoder logic to receive the address identifier of the read request, the retrieved data and the retrieved error correction code, the decoder logic to perform, with the retrieved error correction code, an evaluation of a combination of the address identifier of the read request and the retrieved data, the decoder logic further to generate, based on the evaluation, a signal to indicate whether the location corresponds to the address identifier.

In an embodiment, the device further comprises encoder logic to receive data of a write request and a first address identifier of the write request, the encoder logic to calculate an error correction code for a combination of the first address identifier and the data. The memory access logic is further to service the write request, including the memory access logic to send the data and the error correction code for storage in a location of a memory, the location indicated by the first address identifier, wherein the write request is serviced independent of the memory access logic to send any address identifier corresponding to the location for storage in the location, where the memory access logic to send any such address identifier is in addition to the memory access logic to send the error correction code.

In an embodiment, the combination of the address identifier of the read request and the retrieved data includes a concatenation of the address identifier of the read request and the retrieved data. In an embodiment, the address identifier is a logical address identifier for the location. In an embodiment, the memory access logic is to service the read request includes the memory access logic to access the location while the location does not store any address identifier corresponding to the location, where any such address identifier is distinct from the error correction code.

In an embodiment, the evaluation indicates an error of a bit of the combination, the decoder logic further to determine whether the indicated error of the bit corresponds to an address error. In an embodiment, the indicated error of the bit corresponds to the address error, wherein the signal indicates that the location does not correspond to the address identifier. In an embodiment, the evaluation indicates an error of a bit of the combination, the decoder logic further to determine whether the indicated error of the bit corresponds to a data error. In an embodiment, the decoder logic determines that the location corresponds to the address identifier, the decoder logic further to determine whether the data error is a recoverable error and, where the data error is determined to be a recoverable error, to correct the data error in response to determining that the location corresponds to the address identifier.

In another aspect, a system comprises a memory device and a memory controller to control the memory device, the memory controller including memory access logic to service a read request including an address identifier, including the memory access logic to retrieve, with the address identifier, data and an error correction code from a location of the memory device. The memory device further comprises decoder logic to receive the address identifier of the read request, the retrieved data and the retrieved error correction code, the decoder logic to perform, with the retrieved error correction code, an evaluation of a combination of the address identifier of the read request and the retrieved data, the decoder logic further to generate, based on the evaluation, a signal to indicate whether the location corresponds to the address identifier.

In an embodiment, the memory controller further comprises encoder logic to receive data of a write request and a first address identifier of the write request, the encoder logic to calculate an error correction code for a combination of the first address identifier and the data. The memory access logic is further to service the write request, including the memory access logic to send the data and the error correction code for storage in a location of a memory, the location indicated by the first address identifier, wherein the write request is serviced independent of the memory access logic to send any address identifier corresponding to the location for storage in the location, where the memory access logic to send any such address identifier is in addition to the memory access logic to send the error correction code.

In an embodiment, the combination of the address identifier of the read request and the retrieved data includes a concatenation of the address identifier of the read request and the retrieved data. In an embodiment, the address identifier is a logical address identifier for the location. In an embodiment, the memory access logic is to service the read request includes the memory access logic to access the location while the location does not store any address identifier corresponding to the location, where any such address identifier is distinct from the error correction code.

In an embodiment, the evaluation indicates an error of a bit of the combination, the decoder logic further to determine whether the indicated error of the bit corresponds to an address error. In an embodiment, the indicated error of the bit corresponds to the address error, and wherein the signal indicates that the location does not correspond to the address identifier. In an embodiment, the evaluation indicates an error of a bit of the combination, the decoder logic further to determine whether the indicated error of the bit corresponds to a data error. In an embodiment, the decoder logic determines that the location corresponds to the address identifier, the decoder logic further to determine whether the data error is a recoverable error and, where the data error is determined to be a recoverable error, to correct the data error in response to determining that the location corresponds to the address identifier.

In another aspect, a method comprises receiving a read request including an address identifier, and servicing the read request. Servicing the read request includes, with the address identifier, retrieving data and an error correction code from a location of the memory device. Servicing the read request further includes, with the retrieved error correction code, evaluating a combination of the address identifier of the read request and the retrieved data. The method further comprises, based on the evaluation, generating a signal indicating whether the location corresponds to the address identifier.

In an embodiment, the method further comprises receiving a write request including data and a first address identifier, and servicing the write request. Servicing the write request includes calculating an error correction code for a combination of the first address identifier and the data, and sending the data and the error correction code for storage in a location of a memory device, the location indicated by the first address identifier. The write request is serviced independent of sending any address identifier corresponding to the location for storage in the location, where such sending any address identifier is in addition to the sending the error correction code.

In an embodiment, the address identifier is a logical address identifier for the location. In an embodiment, servicing the read request includes accessing the location while the location does not store any address identifier corresponding to the location, where any such address identifier is distinct from the error correction code. In an embodiment, the evaluation indicates an error of a bit of the combination, the method further comprising determining whether the indicated error of the bit corresponds to an address error.

In an embodiment, the indicated error of the bit corresponds to the address error, and wherein the signal indicates that the location does not correspond to the address identifier. In an embodiment, the evaluation indicates an error of a bit of the combination, the method further comprising determining whether the indicated error of the bit corresponds to a data error. In an embodiment, the evaluation determines that the location corresponds to the address identifier, where the method further comprises determining whether the data error is a recoverable error, and where the data error is determined to be a recoverable error, correcting the data error in response to the evaluation determining that the location corresponds to the address identifier.

In another aspect, a computer-readable storage medium has stored thereon instructions which, when executed by one or more processing units, cause the one or more processing units to perform a method. The method comprises receiving a read request including an address identifier, and servicing the read request. Servicing the read request includes, with the address identifier, retrieving data and an error correction code from a location of the memory device. Servicing the read request further includes, with the retrieved error correction code, evaluating a combination of the address identifier of the read request and the retrieved data. The method further comprises, based on the evaluation, generating a signal indicating whether the location corresponds to the address identifier.

In an embodiment, the method further comprises receiving a write request including data and a first address identifier and servicing the write request. Servicing the write request includes calculating an error correction code for a combination of the first address identifier and the data, and sending the data and the error correction code for storage in a location of a memory device, the location indicated by the first address identifier. The write request is serviced independent of sending any address identifier corresponding to the location for storage in the location, where such sending any address identifier is in addition to the sending the error correction code.

In an embodiment, the address identifier is a logical address identifier for the location. In an embodiment, servicing the read request includes accessing the location while the location does not store any address identifier corresponding to the location, where any such address identifier is distinct from the error correction code.

Techniques and architectures for controlling access to a memory device are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A device comprising:
memory access logic to service a read request including an address identifier, including the memory access logic to retrieve, with the address identifier, data and an error correction code from a location of a memory;
decoder logic to receive the address identifier of the read request, the retrieved data and the retrieved error correction code, the decoder logic to perform, with the retrieved error correction code, an evaluation of a combination of the address identifier of the read request and the retrieved data, the decoder logic further to generate, based on the evaluation, a signal to indicate whether the location corresponds to the address identifier.

2. The device of claim 1, further comprising:
encoder logic to receive data of a write request and a first address identifier of the write request, the encoder logic to calculate an error correction code for a combination of the first address identifier and the data;
wherein the memory access logic further to service the write request, including the memory access logic to send the data and the error correction code for storage in a location of a memory, the location indicated by the first address identifier, wherein the write request is serviced independent of the memory access logic to send any address identifier corresponding to the location for storage in the location, where the memory access logic to send any such address identifier is in addition to the memory access logic to send the error correction code.

3. The device of claim 1, wherein the combination of the address identifier of the read request and the retrieved data includes a concatenation of the address identifier of the read request and the retrieved data.

4. The device of claim 1, wherein the address identifier is a logical address identifier for the location.

5. The device of claim 1, wherein the memory access logic to service the read request includes the memory access logic to access the location while the location does not store any address identifier corresponding to the location, where any such address identifier is distinct from the error correction code.

6. The device of claim 1, wherein the evaluation indicates an error of a bit of the combination, the decoder logic further to determine whether the indicated error of the bit corresponds to an address error.

7. The device of claim 6, wherein the indicated error of the bit corresponds to the address error, and wherein the signal indicates that the location does not correspond to the address identifier.

8. The device of claim 1, wherein the evaluation indicates an error of a bit of the combination, the decoder logic further to determine whether the indicated error of the bit corresponds to a data error.

9. The device of claim 8, wherein the decoder logic determines that the location corresponds to the address identifier, the decoder logic further to determine whether the data error is a recoverable error and, where the data error is determined to be a recoverable error, to correct the data error in response to determining that the location correspond to the address identifier.

10. A system comprising:
a memory device;
a memory controller to control the memory device, the memory controller including:
memory access logic to service a read request including an address identifier, including the memory access logic to retrieve, with the address identifier, data and an error correction code from a location of the memory device;
decoder logic to receive the address identifier of the read request, the retrieved data and the retrieved error correction code, the decoder logic to perform, with the retrieved error correction code, an evaluation of a combination of the address identifier of the read request and the retrieved data, the decoder logic further to generate, based on the evaluation, a signal to indicate whether the location corresponds to the address identifier.

11. The system of claim 10, the memory controller further comprising:
encoder logic to receive data of a write request and a first address identifier of the write request, the encoder logic to calculate an error correction code for a combination of the first address identifier and the data;
wherein the memory access logic further to service the write request, including the memory access logic to send the data and the error correction code for storage in a location of a memory, the location indicated by the first address identifier, wherein the write request is serviced independent of the memory access logic to send any address identifier corresponding to the location for storage in the location, where the memory access logic to send any such address identifier is in addition to the memory access logic to send the error correction code.

12. The system of claim 10, wherein the combination of the address identifier of the read request and the retrieved data includes a concatenation of the address identifier of the read request and the retrieved data.

13. The system of claim 10, wherein the address identifier is a logical address identifier for the location.

14. The system of claim 10, wherein the memory access logic to service the read request includes the memory access logic to access the location while the location does not store any address identifier corresponding to the location, where any such address identifier is distinct from the error correction code.

15. The system of claim 10, wherein the evaluation indicates an error of a bit of the combination, the decoder logic further to determine whether the indicated error of the bit corresponds to an address error.

16. The system of claim 15, wherein the indicated error of the bit corresponds to the address error, and wherein the signal indicates that the location does not correspond to the address identifier.

17. The system of claim 10, wherein the evaluation indicates an error of a bit of the combination, the decoder logic further to determine whether the indicated error of the bit corresponds to a data error.

18. The system of claim 17, wherein the decoder logic determines that the location corresponds to the address identifier, the decoder logic further to determine whether the data error is a recoverable error and, where the data error is determined to be a recoverable error, to correct the data error in response to determining that the location correspond to the address identifier.

19. A method comprising:
receiving a read request including an address identifier;
servicing the read request, including:
with the address identifier, retrieving data and an error correction code from a location of the memory device;
with the retrieved error correction code, evaluating a combination of the address identifier of the read request and the retrieved data; and
based on the evaluation, generating a signal indicating whether the location corresponds to the address identifier.

20. The method of claim 19, further comprising:
receiving a write request including data and a first address identifier;
servicing the write request, including:
calculating an error correction code for a combination of the first address identifier and the data; and
sending the data and the error correction code for storage in a location of a memory device, the location indicated by the first address identifier;
wherein the write request is serviced independent of sending any address identifier corresponding to the location for storage in the location, where such sending any address identifier is in addition to the sending the error correction code.

21. The method of claim 19 wherein the address identifier is a logical address identifier for the location.

22. The method of claim 19 wherein servicing the read request includes accessing the location while the location does not store any address identifier corresponding to the location, where any such address identifier is distinct from the error correction code.

23. The method of claim 19 wherein the evaluation indicates an error of a bit of the combination, the method further comprising determining whether the indicated error of the bit corresponds to an address error.

24. The method of claim 23, wherein the indicated error of the bit corresponds to the address error, and wherein the signal indicates that the location does not correspond to the address identifier.

25. The method of claim 19 wherein the evaluation indicates an error of a bit of the combination, the method further comprising determining whether the indicated error of the bit corresponds to a data error.

26. The method of claim 25, wherein the evaluation determines that the location corresponds to the address identifier, the method further comprising:
determining whether the data error is a recoverable error; and
where the data error is determined to be a recoverable error, correcting the data error in response to the evaluation determining that the location corresponds to the address identifier.

27. A computer-readable storage medium having stored thereon instructions which, when executed by one or more processing units, cause the one or more processing units to perform a method comprising:
receiving a read request including an address identifier;
servicing the read request, including:
with the address identifier, retrieving data and an error correction code from a location of the memory device;
with the retrieved error correction code, evaluating a combination of the address identifier of the read request and the retrieved data; and
based on the evaluation, generating a signal indicating whether the location corresponds to the address identifier.

28. The computer-readable storage medium of claim 27, the method further comprising:
receiving a write request including data and a first address identifier;
servicing the write request, including:
calculating an error correction code for a combination of the first address identifier and the data; and
sending the data and the error correction code for storage in a location of a memory device, the location indicated by the first address identifier;
wherein the write request is serviced independent of sending any address identifier corresponding to the location for storage in the location, where such sending any address identifier is in addition to the sending the error correction code.

29. The computer-readable storage medium of claim 27, wherein the address identifier is a logical address identifier for the location.

30. The computer-readable storage medium of claim 27, wherein servicing the read request includes accessing the location while the location does not store any address identifier corresponding to the location, where any such address identifier is distinct from the error correction code.
